(19) United States
(12) Patent Application Publication
(10) Pub. No.: US 2019/0165768 A1
(43) Pub. Date: May 30, 2019

(54) SIGNAL DRIVER CIRCUIT AND SEMICONDUCTOR APPARATUS USING THE SIGNAL DRIVER CIRCUIT

(71) Applicant: SK hynix Inc., Icheon-si Gyeonggi-do (KR)

(72) Inventor: Hae Kang JUNG, Gwangmyeong-si Gyeonggi-do (KR)

(73) Assignee: SK hynix Inc., Icheon-si Gyeonggi-do (KR)

(21) Appl. No.: 16/030,411

(22) Filed: Jul. 9, 2018

(30) Foreign Application Priority Data
Nov. 30, 2017 (KR) 10-2017-0162983

(51) Int. Cl. H03K 3/037; H03K 7/08

(52) U.S. Cl. CPC H03K 3/037; H03K 7/08

(57) ABSTRACT

A signal driver circuit includes a first inversion driver, a second inversion driver and an emphasis driver. The first inversion driver is configured to receive a first signal, and output a second signal by inversion-driving the first signal. The second inversion driver is configured to receive the second signal, and output a third signal by inversion-driving the second signal. The emphasis driver is configured to receive the third signal, inversion-drive the third signal, and combine the inversion-driven signal to the first signal.

### CROSS-REFERENCES TO RELATED APPLICATION

The present application claims priority under 35 U.S.C. § 119(a) to Korean application number 10-2017-0162983, filed on Nov. 30, 2017, in the Korean Intellectual Property Office, which is incorporated herein by reference in its entirety as set forth in full.

### BACKGROUND

### 1. Technical Field

Various embodiments generally relate to an integrated circuit technology and, more particularly, to a signal driver circuit for driving a signal and semiconductor apparatus using the signal driver circuit.

### 2. Related Art

An electronic device includes a lot of electronic elements, and a computer system includes lots of semiconductor apparatuses comprising a semiconductor. The semiconductor apparatuses of the computer system may communicate with one another by transmitting and receiving a clock signal and data to and from one another. Recently a frequency of a clock signal increases as operation speeds of the semiconductor apparatuses improve.

A semiconductor apparatus includes a clock distribution network such as a clock tree in order to distribute a clock signal to various circuits included therein. The clock tree may distribute a clock signal to various circuits included in the semiconductor apparatus by driving the clock signal. However, it becomes harder to provide a precise clock signal as a frequency of the clock signal increases and a pulse width of the clock signal becomes narrower. Also, a transmission timing of the clock signal may be delayed. Various disclosures have been provided to precisely drive a clock signal and provide the precise clock signal. One of the disclosures focuses on driving a clock signal through pre-emphasis and de-emphasis operations.

### SUMMARY

In an embodiment, a signal driver circuit may be provided. The signal driver may include a first inversion driver configured to receive a first signal, and to output a second signal by inversion-driving the first signal. The signal driver may include a second inversion driver configured to receive the second signal, and to output a third signal by inversion-driving the second signal. The signal driver may include an emphasis driver configured to receive the third signal, to inversion-drive the third signal, and to combine the inversion-driven signal to the first signal.

In an embodiment, a signal driver circuit may be provided. The signal driver may include 2n numbers of inversion drivers configured to output a second signal by inversion-driving a first signal in sequence, where n is an integer equal to or greater than 1. The signal driver may include an emphasis driver configured to inversion-drive the second signal, and to combine the inversion-driven signal to the first signal.

In an embodiment, a signal driver circuit may be provided. The signal driver circuit may include a first driver circuit configured to output a first output signal by inverting a first phase signal 2n number of times, to invert the first output signal, and to combine the inverted signal to the first phase signal. Also, n is an integer equal to or greater than 1.

In an embodiment, a signal driver circuit may be provided. The signal driver circuit may include a first driver circuit configured to generate a first intermediate signal by inverting a first phase signal, and to generate a first output signal by inverting the first intermediate signal. The signal driver circuit may include a second driver circuit configured to generate a second intermediate signal by inverting a second phase signal, and to generate a second output signal by inverting the second intermediate signal. The second phase signal may have a phase difference from the first phase signal. The signal driver circuit may include a first emphasis driver configured to invert the second phase signal, and to combine the inverted signal to the first phase signal. The signal driver circuit may be configured to invert the second intermediate signal, and to combine the inverted signal to the first intermediate signal. The signal driver circuit may be configured to invert the second output signal, and to combine the inverted signal to the first output signal.

### BRIEF DESCRIPTION OF THE DRAWINGS

FIG. 1 a diagram illustrating a representation of an example of a configuration of a signal driver circuit in accordance with an embodiment.

FIGS. 2A to 2C are diagrams illustrating operations of a prior art and a signal driver circuit in accordance with an embodiment.

FIG. 3 is a comparative timing diagram illustrating output signals from a prior art and a signal driver circuit in accordance with an embodiment.

FIG. 4 is a diagram illustrating a representation of an example of a configuration of a signal driver circuit in accordance with an embodiment.

FIG. 5 is a diagram illustrating a representation of an example of an operation of a signal driver circuit in accordance with an embodiment.

FIG. 6 is a diagram illustrating a representation of an example of a configuration of a signal driver circuit in accordance with an embodiment.

FIG. 7 is a diagram illustrating a representation of an example of an operation of a signal driver circuit in accordance with an embodiment.

FIGS. 8A and 8B are diagrams illustrating a representation of an example of a configuration of a signal driver circuit in accordance with an embodiment.

FIGS. 9A and 9B are diagrams illustrating a representation of an example of a configuration of a signal driver circuit in accordance with an embodiment.

FIG. 10 is a wave diagram illustrating an output signal from a signal driver circuit in accordance with an embodiment.

FIG. 11 is a diagram illustrating a representation of an example of a configuration of a signal driver circuit in accordance with an embodiment.

FIG. 12 is a wave diagram illustrating an output signal from the signal driver circuit shown in FIG. 11.

FIG. 13 is a diagram illustrating a representation of an example of a configuration of a signal driver circuit in accordance with an embodiment.

FIG. 14 is a diagram illustrating a representation of an example of a configuration of a semiconductor apparatus in accordance with an embodiment.

### DETAILED DESCRIPTION

Hereinafter, a semiconductor apparatus according to various embodiments will be described below with reference to the accompanying drawings through examples of embodiments.

In accordance with an embodiment, a signal driver circuit may receive an input signal and may generate an output signal. The signal driver circuit may perform an emphasis operation on the output signal. The emphasis operation may be a de-emphasis operation and/or a pre-emphasis operation. The signal driver circuit may include a main driver and an emphasis driver. The main driver may inversion-drive an input signal 2n times (n is an integer equal to or greater than 1). The emphasis driver may inversion-drive a signal output from the main driver, and may combine the inversion-driven signal into a signal to be input to the main driver. The main driver and the emphasis driver may be commonly applied to signal driver circuits in accordance with various embodiment. The emphasis driver may form a peak of the output signal. The peak may have an amplitude and pulse width. The emphasis driver may have a variable driving force and a variable delayed time. The emphasis driver may change an emphasis voltage and emphasis time by adjusting driving force and delayed time. The emphasis driver may change the amplitude and the emphasis voltage of the peak by adjusting the driving force thereof. The emphasis driver may change the pulse width and the emphasis time of the peak by adjusting the delayed time thereof. Hereinafter, described with reference to the figures will be a signal driver circuit in accordance with various embodiments.

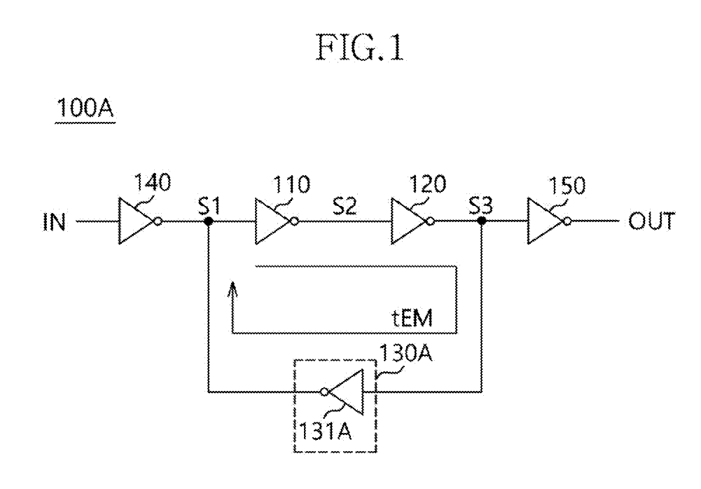

FIG. 1 a diagram illustrating a representation of an example of a configuration of a signal driver circuit 100A in accordance with an embodiment. Referring to FIG. 1, the signal driver circuit 100A may include a first inversion driver 110, a second inversion driver 120 and an emphasis driver 130A. The first inversion driver 110 and the second inversion driver 120 may be included in a main driver. The first inversion driver 110 may receive a first signal S1 and may output a second signal S2 by inversion-driving the first signal S1. For example, the first inversion driver 110 may be an inverter configured to output the second signal S2 by inverting the first signal S1. The second inversion driver 120 may receive the second signal S2 and may output a third signal S3 by inversion-driving the second signal S2. For example, the second inversion driver 120 may be an inverter configured to output the third signal S3 by inverting the second signal S2. The emphasis driver 130A may receive the third signal S3. The emphasis driver 130A may inversion-drive the third signal S3 and may combine the inversion-driven signal to the first signal S1. For example, the emphasis driver 130A may be an inverter 131A configured to invert the third signal S3 and output the inverted signal. Therefore, the main driver may generate the third signal S3 by inverting the first signal S1 twice. The emphasis driver 130A may invert the third signal S3 once and combine the inverted signal to the first signal S1.

The signal driver circuit 100A may further include an input inversion driver 140 and an output inversion driver 150. The input inversion driver 140 and the output inversion driver 150 as well as the first inversion driver 110 and the second inversion driver 120 may be included in the main driver. The input inversion driver 140 may receive an input signal IN and may output the first signal S1 by inversion-driving the input signal IN. For example, the input signal IN may be a clock signal configured to toggle with a predetermined period. For example, the input inversion driver 140 may be an inverter configured to output the first signal S1 by inverting the input signal IN. The output inversion driver 150 may receive the third signal S3 and may output an output signal OUT by inversion-driving the third signal S3. For example, the output inversion driver 150 may be an inverter configured to output the output signal OUT by inverting the third signal S3. The emphasis driver 130A may perform an emphasis operation to the output signal OUT. The emphasis driver 130A may form a peak of the output signal OUT by performing an emphasis operation to the output signal OUT. The peak may occur when the output signal OUT transits from a logic level to another logic level.

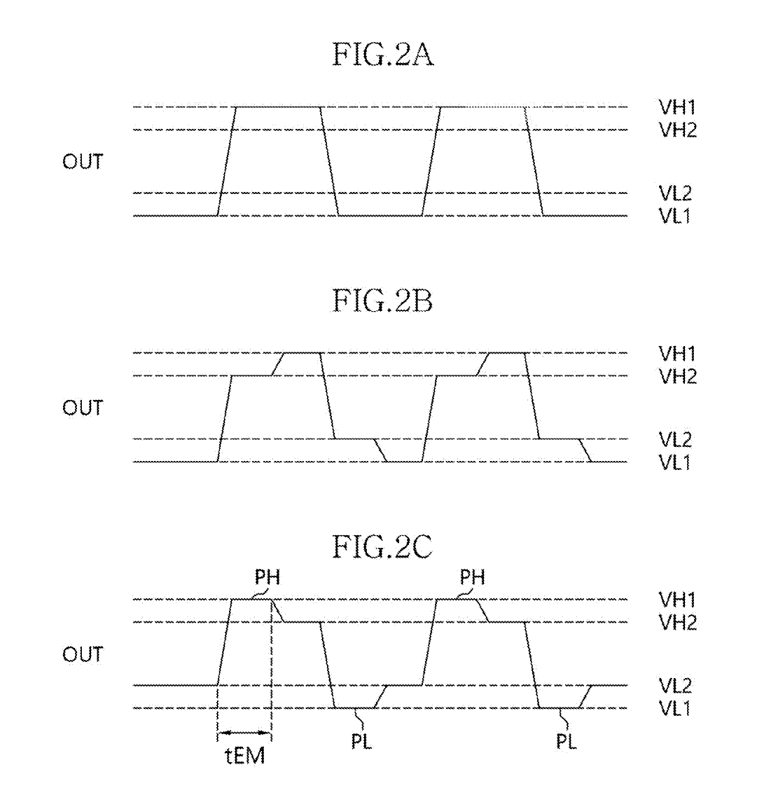

FIG. 2A is a diagram illustrating an ideal waveform of an output signal OUT generated without an emphasis driver, and FIG. 2B is a diagram illustrating a substantial waveform of the output signal OUT generated without the emphasis driver. When the emphasis driver 130A shown in FIG. 1 is not provided, the input signal IN may be sequentially inverted by the input inversion driver 140, the first inversion driver 110, the second inversion driver 120 and the output inversion driver 150, and the output signal OUT may ideally have a waveform as shown in FIG. 2A. A high level of the output signal OUT may be of a first high voltage VH1, and a low level of the output signal OUT may be of a first low voltage VL1. However, when a signal is substantially inverted by the inversion drivers 110, 120, 140 and 150, that is, when the signal transit from a high level to a low level or from a low level to a high level, a rising slope and a falling slope of the signal may be reduced. Referring to FIG. 2B, when the output signal OUT transits from a low level to a high level, the output signal OUT at most reaches a second high voltage VH2 lower than the first high voltage VH1. The output signal OUT may reach the first high voltage VH1 after a predetermined time elapses. In the similar way, when the output signal OUT transits from a high level to a low level, the output signal OUT at most reaches a second low voltage VL2 higher than the first low voltage VL1. The output signal OUT may reach the first low voltage VL after a predetermined time elapses. Therefore, the output signal OUT cannot be transferred to another circuit precisely and promptly and a margin for receiving the output signal OUT can be reduced in the another circuit. As a frequency of the input signal IN becomes higher, the amount of margin reduction becomes greater.

FIG. 2C is a diagram illustrating a representation of an example of an operation of the signal driver circuit 100A in accordance with an embodiment. In accordance with an embodiment, the signal driver circuit 100A may include the emphasis driver 130A. The emphasis driver 130A may form the peak P of the output signal OUT, which may increase a margin for another circuit to precisely and promptly receive the signal output from the signal driver circuit 100A. As shown in FIG. 2C, when the output signal OUT transits from a low level to a high level, the output signal OUT may reach the first high voltage VH1 during an emphasis time tEM, and may have a level of the second high voltage VH2 after the emphasis time tEM. When the output signal OUT transits from a high level to a low level, the output signal OUT may reach the first low voltage VL1 during the emphasis time tEM, and may have a level of the second low voltage VL2 after the emphasis time tEM. An emphasis operation may be performed to the output signal OUT through a coupling relationship between the main driver and the emphasis driver, and a high level peak PH and a low level peak PL of the output signal OUT may be formed. Further, a subsequent level transition may be easily performed by decreasing a high level of the output signal OUT or increasing a low level of the output signal OUT after forming the high level peak PH and the low level peak PL of the output signal OUT. The emphasis time tEM may correspond to a pulse width of the high level peak PH and the low level peak PL of the output signal OUT. As shown in FIG. 1, the emphasis time tEM may be an amount of time delayed by the first inversion driver 110, the second inversion driver 120 and the emphasis driver 130A, or a propagation delay time during which the first signal S1 propagates the first inversion driver 110, the second inversion driver 120 and the emphasis driver 130A. In an embodiment, a main driver including 2n numbers of inversion drivers configured to output a second signal by sequentially inversion-driving a first signal, where n is an integer equal to or greater than 1, and an emphasis driver configured to inversion-drive the second signal, and to combine the inversion-driven signal to the first signal. The input inversion driver may be configured to receive an input signal, and to output the first signal by inversion-driving the input signal at least n number of times. The output inversion driver configured to receive the second signal, and to output an output signal by inversion-driving the second signal at least n number of times. The emphasis driver may form a peak of the output signal by performing an emphasis operation to the output signal, and a driving force of the emphasis driver may be variable to adjust an amplitude of the peak of the output signal. The signal driver circuit may increase a pulse width of the peak as the n becomes greater.

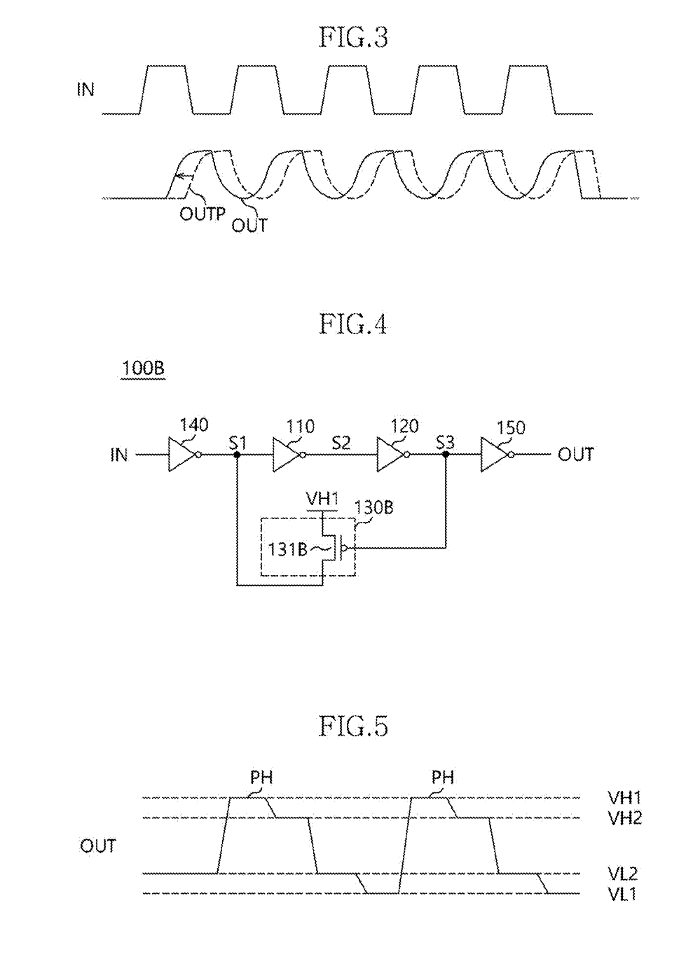

FIG. 3 is a timing diagram comparing the output signal OUT generated from the signal driver circuit 100A in accordance with an embodiment with an output signal OUTP. Referring to FIG. 3, a waveform with a solid line indicates the output signal OUT generated from the signal driver circuit 100A and a waveform with a broken line indicates the output signal OUTP generated without driving an input signal through an emphasis operation. When the signal driver circuit 100A generates the output signal OUT by driving the input signal IN, through the emphasis operation, the signal driver circuit 100A may output the output signal OUT prior to when the output signal OUTP is output. Therefore, the signal driver circuit 100A may minimize delay and may transmit a signal at prompt timing.

In an embodiment, the emphasis driver 130A may be implemented with a pull-up driver or a pull-down driver instead of the inverter. When the emphasis driver 130A is implemented with a pull-up driver, the emphasis driver 130A may form only the high level peak PH of the output signal OUT by pull-up-driving the first signal S1 based on the third signal S3. When the emphasis driver 130A is implemented with a pull-down driver, the emphasis driver 130A may form only the low level peak PL of the output signal OUT by pull-down-driving the first signal S1 based on the third signal S3.

FIG. 4 is a diagram illustrating a representation of an example of a configuration of a signal driver circuit 1008 in accordance with an embodiment. Referring to FIG. 4, the signal driver circuit 1008 may include a first inversion driver 110, a second inversion driver 120 and an emphasis driver 1308. The first inversion driver 110 may receive a first signal S1 and may output a second signal S2 by inversion-driving the first signal S1. The second inversion driver 120 may receive the second signal S2 and may output a third signal S3 by inversion-driving the second signal S2. The emphasis driver 1308 may receive the third signal S3. The emphasis driver 1308 may inversion-drive the third signal S3 and may combine the inversion-driven signal to the first signal S1. For example, the emphasis driver 1308 may be a pull-up driver configured to additionally pull-up-driving the first signal S1 when the third signal S3 is of a low level.

The signal driver circuit 1008 may further include an input inversion driver 140 and an output inversion driver 150. The input inversion driver 140 may receive an input signal IN and may output the first signal S1 by inversion-driving the input signal IN. The output inversion driver 150 may receive the third signal S3 and may output an output signal OUT by inversion-driving the third signal S3.

The emphasis driver 130B may perform an emphasis operation to the output signal OUT. The emphasis driver 130B may form a peak of the output signal OUT by performing an emphasis operation to the output signal OUT. The peak may occur when the output signal OUT transits from a low level to a high level. The emphasis driver 130B may include a first transistor 131B. The first transistor 131B may be a P-channel MOS transistor. In an embodiment, the first transistor 131B may be an N-channel MOS transistor and the emphasis driver 130B may be implemented with another switching element. The first transistor 131B may receive the third signal S3 at its gate, may be coupled to a first high voltage VH1 at its source and may be coupled to the first signal S1 at its drain.

FIG. 5 is a diagram illustrating a representation of an example of an operation of the signal driver circuit 1008 in accordance with an embodiment. In accordance with an embodiment, the signal driver circuit 1008 may include the emphasis driver 1308. The emphasis driver 1308 may form a high level peak PH of the output signal OUT, which may increase a margin for another circuit to precisely and promptly receive the signal output from the signal driver circuit 1008. As shown in FIG. 5, when the output signal OUT transits from a low level to a high level, the output signal OUT may reach the first high voltage VH1, and then may decrease to have a level of the second high voltage VH2 thereby forming the high level peak PH. When the output signal OUT transits from a high level to a low level, the output signal OUT may reach the second low voltage VL2, and then may decrease to have a level of the first low voltage VL1. The signal driver circuit 100B may include the emphasis driver 130B implemented with a pull-up driver, and may perform an emphasis operation only when the output signal OUT transits from a low level to a high level. Therefore, the emphasis driver 130B may form only the high level peak PH of the output signal OUT.

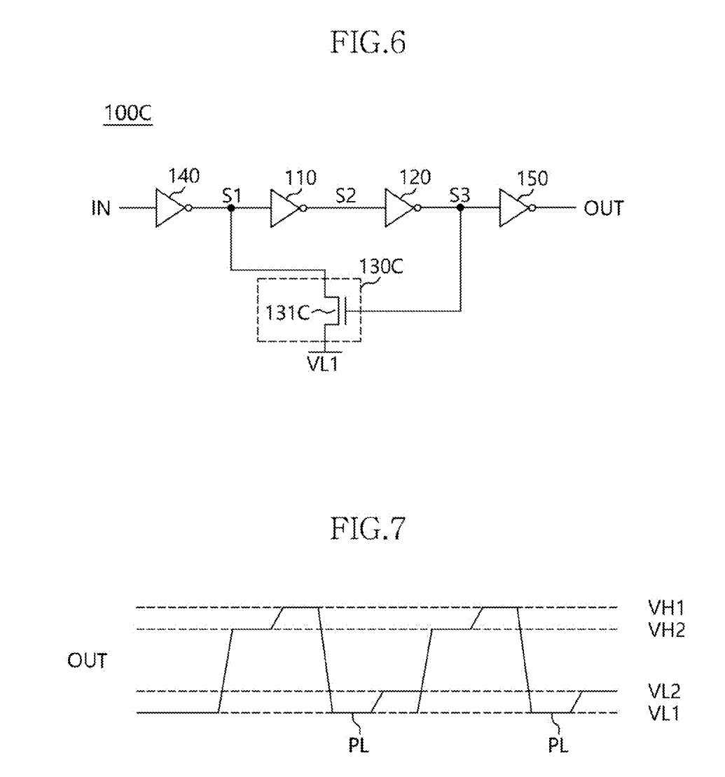

FIG. 6 is a diagram illustrating a representation of an example of a configuration of a signal driver circuit 100C in accordance with an embodiment. Referring to FIG. 6, the signal driver circuit 100C may include a first inversion driver 110, a second inversion driver 120 and an emphasis driver 130C. The first inversion driver 110 may receive a first signal S1 and may output a second signal S2 by inversion-driving the first signal S1. The second inversion driver 120 may receive the second signal S2 and may output a third signal S3 by inversion-driving the second signal S2. The emphasis driver 130C may receive the third signal S3. The emphasis driver 130C may inversion-drive the third signal S3 and may combine the inversion-driven signal to the first signal S1. For example, the emphasis driver 130C may be a pull-down driver configured to additionally pull-down-driving the first signal S1 when the third signal S3 is of a high level.

The signal driver circuit 100C may further include an input inversion driver 140 and an output inversion driver 150. The input inversion driver 140 may receive an input signal IN and may output the first signal S1 by inversion-driving the input signal IN. The output inversion driver 150 may receive the third signal S3 and may output an output signal OUT by inversion-driving the third signal S3.

The emphasis driver 130C may perform an emphasis operation to the output signal OUT. The emphasis driver 130C may form a peak of the output signal OUT by performing an emphasis operation to the output signal OUT. The peak may occur when the output signal OUT transits from a high level to a low level. The emphasis driver 130C may include a second transistor 131C. The second transistor 131C may be an N-channel MOS transistor. In an embodiment, the second transistor 131C may be a P-channel MOS transistor and the emphasis driver 130C may be implemented with another switching element. The second transistor 131C may receive the third signal S3 at its gate, may be coupled to a first low voltage VL1 at its source and may be coupled to the first signal S1 at its drain.

FIG. 7 is a diagram illustrating a representation of an example of an operation of the signal driver circuit 100C in accordance with an embodiment. In accordance with an embodiment, the signal driver circuit 100C may include the emphasis driver 130C. The emphasis driver 130C may form a low level peak PL of the output signal OUT, which may increase a margin for another circuit to precisely and promptly receive the signal output from the signal driver circuit 100C. As shown in FIG. 7, when the output signal OUT transits from a high level to a low level, the output signal OUT may reach the first low voltage VL1, and then may increase to have a level of the second low voltage VL2 thereby forming the low level peak PL. When the output signal OUT transits from a low level to a high level, the output signal OUT may reach the second high voltage VH2, and then may increase to have a level of the first high voltage VH1. The signal driver circuit 100C may include the emphasis driver 130C implemented with a pull-down driver, and may perform an emphasis operation only when the output signal OUT transits from a high level to a low level. Therefore, the emphasis driver 130C may form only the low level peak PL of the output signal OUT.

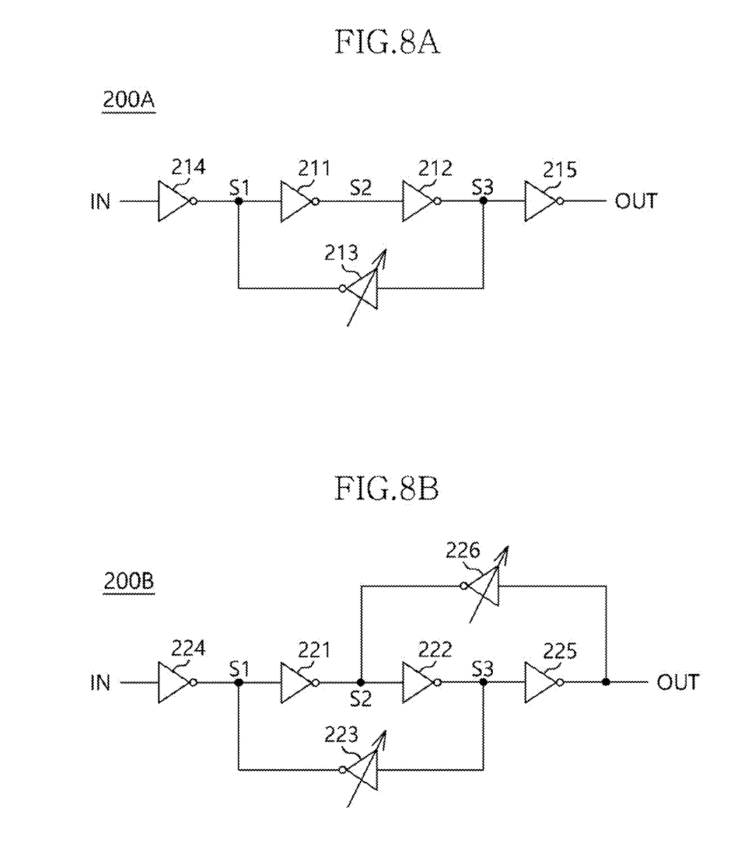

FIGS. 8A and 8B are diagrams illustrating a representation of an example of a configuration of signal driver circuits 200A and 200B in accordance with an embodiment. Referring to FIGS. 8A and 8B, the signal driver circuits 200A and 200B may control amplitude of a peak and an emphasis voltage of the output signal OUT. Referring to FIG. 8A, the signal driver circuit 200A may include an input inversion driver 214, a first inversion driver 211, a second inversion driver 212 and an output inversion driver 215. The input inversion driver 214 may generate a first signal S1 by inverting an input signal IN. The first inversion driver 211 may generate a second signal S2 by inverting the first signal S1. The second inversion driver 212 may generate a third signal S3 by inverting the second signal S2. The output inversion driver 215 may generate the output signal OUT by inverting the third signal S3. The signal driver circuit 200A may include an emphasis driver 213. The emphasis driver 213 may invert the third signal S3 and may combine the inverted signal to the first signal S1.

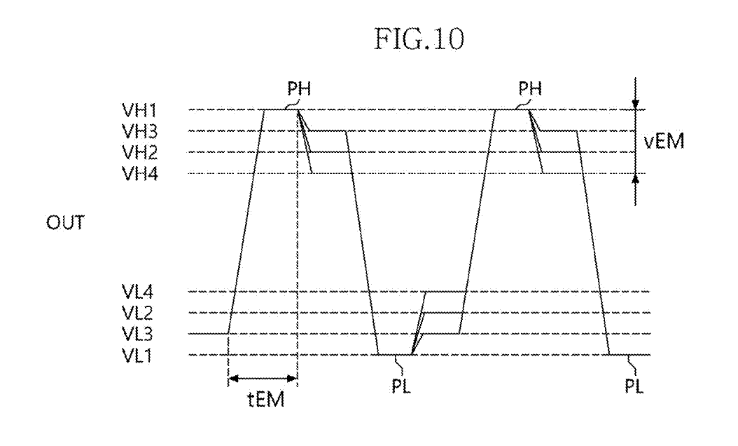

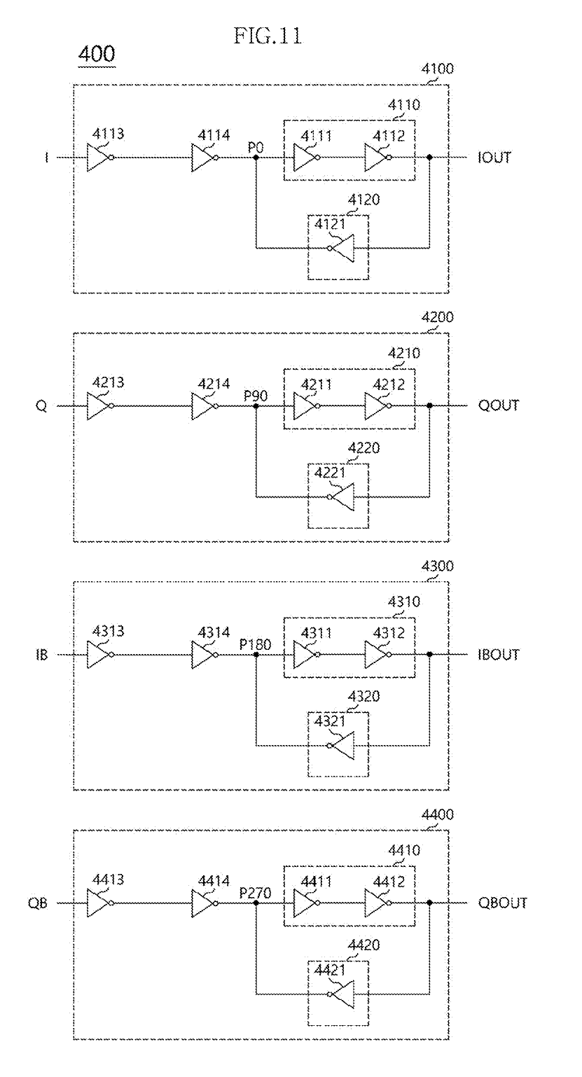

Referring to FIG. 8A, driving force of the emphasis driver 213 may be variable. The driving force of the emphasis driver 213 may be variable in order to change the amplitude of the peak of the output signal OUT. The amplitude of the peak may be determined according to the emphasis voltage vEM shown in FIG. 10. As described with reference to FIG. 2C, the emphasis driver 213 may form the peak during the emphasis time tEM and then decrease the high level of the output signal OUT or increase the low level of the output signal OUT after the emphasis time tEM. The level of the emphasis voltage vEM may correspond to the decreased voltage level or the increased voltage level. For example, as the driving force of the emphasis driver 213 becomes greater, the level of the emphasis voltage vEM may become greater and thus the decreased voltage level and/or the increased voltage level may become greater and the amplitude of the peak may become greater. For example, as the driving force of the emphasis driver 213 lessens, the level of the emphasis voltage vEM may lessen and thus the decreased voltage level and/or the increased voltage level may lessen and the amplitude of the peak may lessen.

Referring to FIG. 8B, the signal driver circuit 200B may include an input inversion driver 224, a first inversion driver 221, a second inversion driver 222 and an output inversion driver 225. The input inversion driver 224 may generate a first signal S1 by inverting an input signal IN. The first inversion driver 221 may generate a second signal S2 by inverting the first signal S1. The second inversion driver 222 may generate a third signal S3 by inverting the second signal S2. The output inversion driver 225 may generate the output signal OUT by inverting the third signal S3. The signal driver circuit 200B may include a first emphasis driver 223 and a second emphasis driver 226. The first emphasis driver 223 may receive the third signal S3, may invert the third signal S3 and may combine the inverted signal to the first signal S1. The second emphasis driver 226 may receive the output signal OUT, may invert the output signal OUT and may combine the inverted signal to the second signal S2.

The driving force of each of the first emphasis driver 223 and the second emphasis driver 226 may be variable, which is similar to the emphasis driver 213 described with reference to FIG. 8A. The driving force of each of the first emphasis driver 223 and the second emphasis driver 226 may be variable in order to change the amplitude of the peak of the output signal OUT. The driving force of the second emphasis driver 226 may be the same as or different from the driving force of the first emphasis driver 223. In an embodiment, the second emphasis driver 226 may be changed and/or modified for various coupling relationship. For example, the second emphasis driver 226 may receive the second signal S2, may invert the second signal S2 and may combine the inverted signal to the input signal IN.

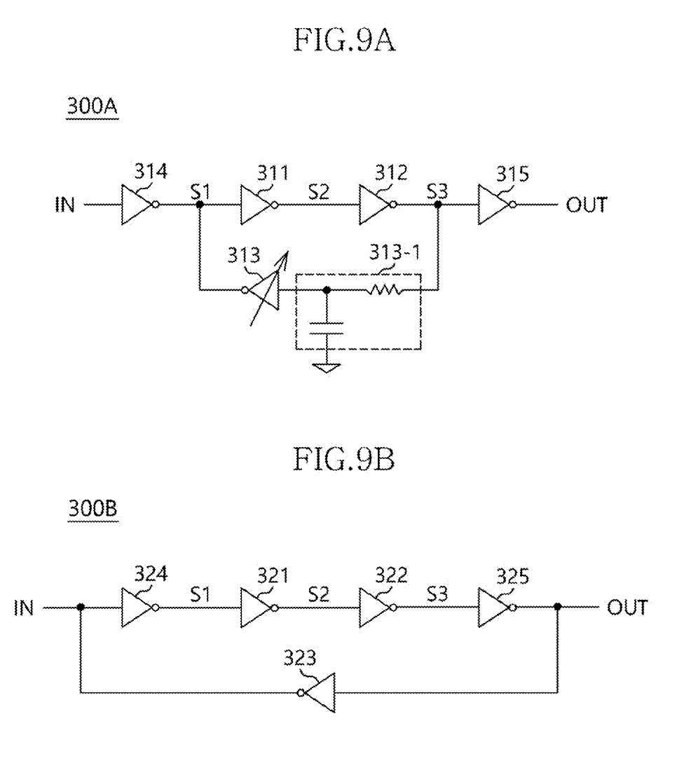

FIGS. 9A and 9B are diagrams illustrating a representation of an example of a configuration of signal driver circuits 300A and 300B in accordance with an embodiment. Referring to FIGS. 9A and 9B, the signal driver circuits 300A and 300B may control a pulse width of a peak of the output signal OUT and/or the emphasis time tEM. Referring to FIG. 9A, the signal driver circuit 300A may include an input inversion driver 314, a first inversion driver 311, a second inversion driver 312 and an output inversion driver 315. The input inversion driver 314 may generate a first signal S1 by inverting an input signal IN. The first inversion driver 311 may generate a second signal S2 by inverting the first signal S1. The second inversion driver 312 may generate a third signal S3 by inverting the second signal S2. The output inversion driver 315 may generate the output signal OUT by inverting the third signal S3. The signal driver circuit 300A may include an emphasis driver 313. The emphasis driver 313 may receive the third signal S3, may invert the third signal S3 and may combine the inverted signal to the first signal S1. The emphasis driver 313 may further include a RC delay unit 313-1. The emphasis driver 313 may control the pulse width of the peak of the output signal OUT by adjusting the emphasis time tEM. The emphasis time tEM may change as an amount of delay of the RC delay unit 313-1 changes. For example, as an amount of delay of the RC delay unit 313-1 increases, the emphasis time tEM may increase and the pulse width of the peak may increase. For example, as an amount of delay of the RC delay unit 313-1 lessens, the emphasis time tEM may lessen and the pulse width of the peak may lessen.

Referring to FIG. 9B, the signal driver circuit 300B may include an input inversion driver 324, a first inversion driver 321, a second inversion driver 322 and an output inversion driver 325. The input inversion driver 324 may generate a first signal S1 by inverting an input signal IN. The first inversion driver 321 may generate a second signal S2 by inverting the first signal S1. The second inversion driver 322 may generate a third signal S3 by inverting the second signal S2. The output inversion driver 325 may generate the output signal OUT by inverting the third signal S3. The signal driver circuit 300B may include an emphasis driver 323. The emphasis driver 323 may receive the output signal OUT, may invert the output signal OUT and may combine the inverted signal to the input signal IN. The emphasis driver 323 may increase the pulse width of the output signal OUT by increasing the emphasis time tEM. The emphasis driver 323 may increase the emphasis time tEM without an element for the delay such as the RC delay unit 313-1, which is different from the emphasis driver 313 described with reference to FIG. 9A. Since the emphasis time tEM is determined by the delayed time of the input inversion driver 324, the first inversion driver 321, the second inversion driver 322 and the output inversion driver 325, sufficient delay time may be secured. The signal driver circuit 300B may generate the output signal OUT by inverting the input signal IN four times. However, it may be sufficient to invert the output signal OUT once and combine the inverted signal to the input signal IN for the emphasis operation to the output signal OUT. That is, the emphasis driver may be sufficient to be implemented with a single inverter (i.e., 323) while the main driver is implemented with four inverters (i.e., 324, 321, 322, and 325).

FIG. 10 is a wave diagram illustrating an output signal from a signal driver circuit in accordance with an embodiment. Referring to FIG. 10, the output signal OUT may include a peak P, the high level peak PH may have a level of a first high voltage VH1 and a low level peak PL may have a level of a first low voltage VL1. A third high voltage VH3 may be lower than the first high voltage VH1, a second high voltage VH2 may be lower than the third high voltage VH3, a fourth high voltage VH4 may be lower than the second high voltage VH2. A third low voltage VL3 may be higher than the first low voltage VL1, a second low voltage VL2 may be higher than the third low voltage VL3 and a fourth low voltage VL4 may be higher than the second low voltage VL2 and may be lower than the fourth high voltage VH4. The emphasis voltage vEM may change by the signal driver circuits 200A and 200B described with reference to FIGS. 8A and 8B. For example, when the driving force of each of the emphasis drivers 213, 223 and 226 included in the signal driver circuits 200A and 200B is small, the output signal OUT may decrease from the first high voltage VH1 to the third high voltage VH3 and the pulse width of the high level peak PH may be determined between the first high voltage VH1 and the third high voltage VH3. Also, the output signal OUT may increase from the first low voltage VL1 to the third low voltage VL3 and the pulse width of the low level peak PL may be determined between the third low voltage VL3 and the first low voltage VL1. For example, when the driving force of each of the emphasis drivers 213, 223 and 226 included in the signal driver circuits 200A and 200B is intermediate, the output signal OUT may decrease from the first high voltage VH1 to the second high voltage VH2 and the pulse width of the high level peak PH may be determined between the first high voltage VH1 and the second high voltage VH2. Also, the output signal OUT may increase from the first low voltage VL1 to the second low voltage VL2 and the pulse width of the low level peak PL may be determined between the second low voltage VL2 and the first low voltage VL1. For example, when the driving force of each of the emphasis drivers 213, 223 and 226 included in the signal driver circuits 200A and 200B is great, the output signal OUT may decrease from the first high voltage VH1 to the fourth high voltage VH4 and the pulse width of the high level peak PH may be determined between the first high voltage VH1 and the fourth high voltage VH4. Also, the output signal OUT may increase from the first low voltage VL1 to the fourth low voltage VL4 and the pulse width of the low level peak PL may be determined between the fourth low voltage VL4 and the first low voltage VL1.

The emphasis time tEM may change by the signal driver circuits 300A and 300B described with reference to FIGS. 9A and 9B. For example, as the emphasis time tEM increases, the pulse widths of the high level peak PH and the low level peak PL may increase. For example, as the emphasis time tEM lessens, the pulse widths of the high level peak PH and the low level peak PL may lessen. The embodiments described with reference to FIGS. 8A to 9B may not be independent from one another, and various modified embodiments may be provided by combining one or more among the embodiments described with reference to FIGS. 8A to 9B.

FIG. 11 is a diagram illustrating a representation of an example of a configuration of a signal driver circuit 400 in accordance with an embodiment. Referring to FIG. 11, the signal driver circuit 400 may include a first driver circuit 4100. The first driver circuit 4100 may output a first output signal IOUT by inverting a first phase signal P0 by a number of 2n times (n is an integer equal to or greater than 1), may invert the first output signal IOUT, and may combine the inverted signal to the first phase signal P0. The signal driver circuit 400 may further include at least one driver circuit. Referring to FIG. 11, the signal driver circuit 400 may further include a second driver circuit 4200, a third driver circuit 4300 and a fourth driver circuit 4400. The second driver circuit 4200 may output a second output signal QOUT by inverting a second phase signal P90 by a number of 2n times, may invert the second output signal QOUT, and may combine the inverted signal to the second phase signal P90. The second phase signal P90 may have a phase difference of 90 degrees from the first phase signal P0. The third driver circuit 4300 may output a third output signal IBOUT by inverting a third phase signal P180 by a number of 2n times, may invert the third output signal IBOUT, and may combine the inverted signal to the third phase signal P180. The third phase signal P180 may have a phase difference of 90 degrees from the second phase signal P90 and may have a phase difference of 180 degrees from the first phase signal P0. The fourth driver circuit 4400 may output a fourth output signal QBOUT by inverting a fourth phase signal P270 by a number of 2n times, may invert the fourth output signal QBOUT, and may combine the inverted signal to the fourth phase signal P270. The fourth phase signal P270 may have a phase difference of 90 degrees from the second phase signal P180, may have a phase difference of 180 degrees from the second phase signal P90 and may have a phase difference of 270 degrees from the first phase signal P0. The signal driver circuit 400 may include the first to fourth driver circuits 4100, 4200, 4300 and 4400, may drive the first to fourth phase signals P0, P90, P180 and P270 having different phases from one another, and may output the driven signals as the first to fourth output signals IOUT, QOUT, IBOUT and QBOUT, respectively. Further, the signal driver circuit 400 may perform an emphasis operation to the first to fourth output signals IOUT, QOUT, IBOUT and QBOUT.

The first driver circuit 4100 may include a first main driver 4110 and a first emphasis driver 4120. The first main driver 4110 may include 2n numbers of inverters configured to invert the first phase signal P0 by a number of 2n times in sequence. FIG. 11 exemplifies the first main driver 4110 including two inverters. The first main driver 4110 may include a first inverter 4111 and a second inverter 4112. The first inverter 4111 may invert the first phase signal P0, and the second inverter 4112 may invert the output of the first inverter 4111 and may output the first output signal IOUT. The first emphasis driver 4120 may include a single inverter configured to invert the first output signal IOUT once. The first emphasis driver 4120 may include a third inverter 4121. The first driver circuit 4100 may further include a fourth inverter 4113 and a fifth inverter 4114. The fourth inverter 4113 may invert a first input signal I, and the fifth inverter 4114 may invert the output of the fourth inverter 4113 and may output the first phase signal PO. In an embodiment, the fourth inverter 4113 and the fifth inverter 4114 as well as the first inverter 4111 and the second inverter 4112 may be included in the first main driver 4110. Therefore, the first main driver 4110 may generate the first output signal IOUT by inverting the first input signal I four times. In an embodiment, the first emphasis driver 4120 may be coupled between the first output signal IOUT and the first input signal I. Here, the third inverter 4121 of the first emphasis driver 4120 may invert the first output signal IOUT and may combine the inverted signal to the first input signal I.

The second driver circuit 4200 may include a second main driver 4210 and a second emphasis driver 4220. The second main driver 4210 may include 2n numbers of inverters configured to invert the second phase signal P90 by a number of 2n times in sequence. FIG. 11 exemplifies the second main driver 4210 including two inverters. The second main driver 4210 may include a first inverter 4211 and a second inverter 4212. The first inverter 4211 may invert the second phase signal P90, and the second inverter 4212 may invert the output of the first inverter 4211 and may output the second output signal QOUT. The second emphasis driver 4220 may include a single inverter configured to invert the second output signal QOUT once. The second emphasis driver 4220 may include a third inverter 4221. The second driver circuit 4200 may further include a fourth inverter 4213 and a fifth inverter 4214. The fourth inverter 4213 may invert a second input signal Q, and the fifth inverter 4214 may invert the output of the fourth inverter 4213 and may output the second phase signal P90. In an embodiment, the fourth inverter 4213 and the fifth inverter 4214 as well as the first inverter 4211 and the second inverter 4212 may be included in the second main driver 4210. Therefore, the second main driver 4210 may generate the second output signal QOUT by inverting the input signal Q four times. In an embodiment, the second emphasis driver 4220 may be coupled between the second output signal QOUT and the second input signal Q. Here, the third inverter 4221 of the second emphasis driver 4220 may invert the second output signal QOUT and may combine the inverted signal to the second input signal Q.

The third driver circuit 4300 may include a third main driver 4310 and a third emphasis driver 4320. The third main driver 4310 may include 2n numbers of inverters configured to invert the third phase signal P180 by a number of 2n times in sequence. FIG. 11 exemplifies the third main driver 4310 including two inverters. The third main driver 4310 may include a first inverter 4311 and a second inverter 4312. The first inverter 4311 may invert the third phase signal P180, and the second inverter 4312 may invert the output of the first inverter 4311 and may output the third output signal IBOUT. The third emphasis driver 4320 may include a single inverter configured to invert the third output signal IBOUT once. The third emphasis driver 4320 may include a third inverter 4321. The third driver circuit 4300 may further include a fourth inverter 4313 and a fifth inverter 4314. The fourth inverter 4313 may invert a third input signal IB, and the fifth inverter 4314 may invert the output of the fourth inverter 4313 and may output the third phase signal P180. In an embodiment, the fourth inverter 4313 and the fifth inverter 4314 as well as the first inverter 4311 and the second inverter 4312 may be included in the third main driver 4310. Therefore, the third main driver 4310 may generate the third output signal IBOUT by inverting the third input signal IB four times. In an embodiment, the third emphasis driver 4320 may be coupled between the third output signal IBOUT and the third input signal IB. Here, the third inverter 4321 of the third emphasis driver 4320 may invert the third output signal IBOUT and may combine the inverted signal to the third input signal IB.

The fourth driver circuit 4400 may include a fourth main driver 4410 and a fourth emphasis driver 4420. The fourth main driver 4410 may include 2n numbers of inverters configured to invert the fourth phase signal P270 by a number of 2n times in sequence. FIG. 11 exemplifies the fourth main driver 4410 including two inverters. The fourth main driver 4410 may include a first inverter 4411 and a second inverter 4412. The first inverter 4411 may invert the fourth phase signal P270, and the second inverter 4412 may invert the output of the first inverter 4411 and may output the fourth output signal QBOUT. The fourth emphasis driver 4420 may include a single inverter configured to invert the fourth output signal QBOUT once. The fourth emphasis driver 4420 may include a third inverter 4421. The fourth driver circuit 4400 may further include a fourth inverter 4413 and a fifth inverter 4414. The fourth inverter 4413 may invert a fourth input signal QB, and the fifth inverter 4414 may invert the output of the fourth inverter 4413 and may output the fourth phase signal P270. In an embodiment, the fourth inverter 4413 and the fifth inverter 4414 as well as the first inverter 4411 and the second inverter 4412 may be included in the fourth main driver 4410. Therefore, the fourth main driver 4410 may generate the fourth output signal QBOUT by inverting the fourth input signal QB four times. In an embodiment, the fourth emphasis driver 4420 may be coupled between the fourth output signal QBOUT and the fourth input signal QB. Here, the third inverter 4421 of the fourth emphasis driver 4420 may invert the fourth output signal QBOUT and may combine the inverted signal to the fourth input signal QB.

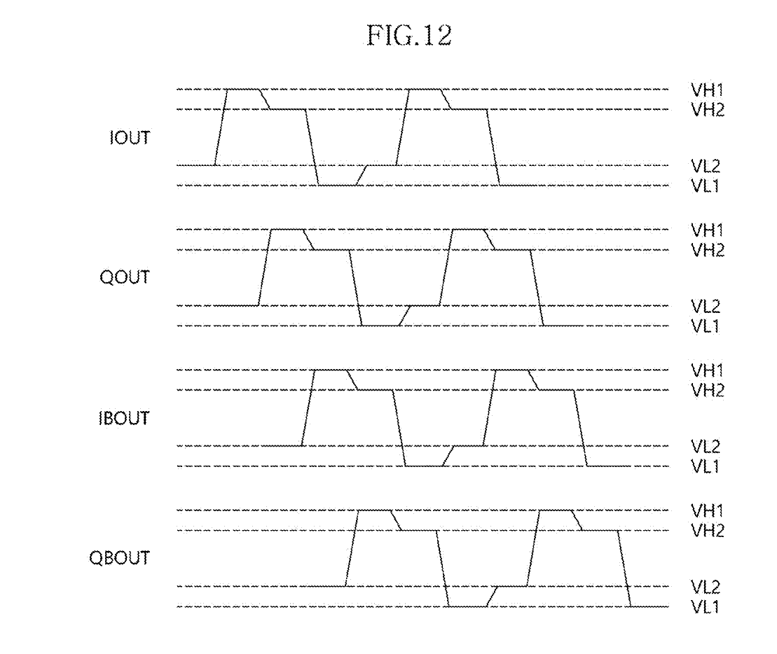

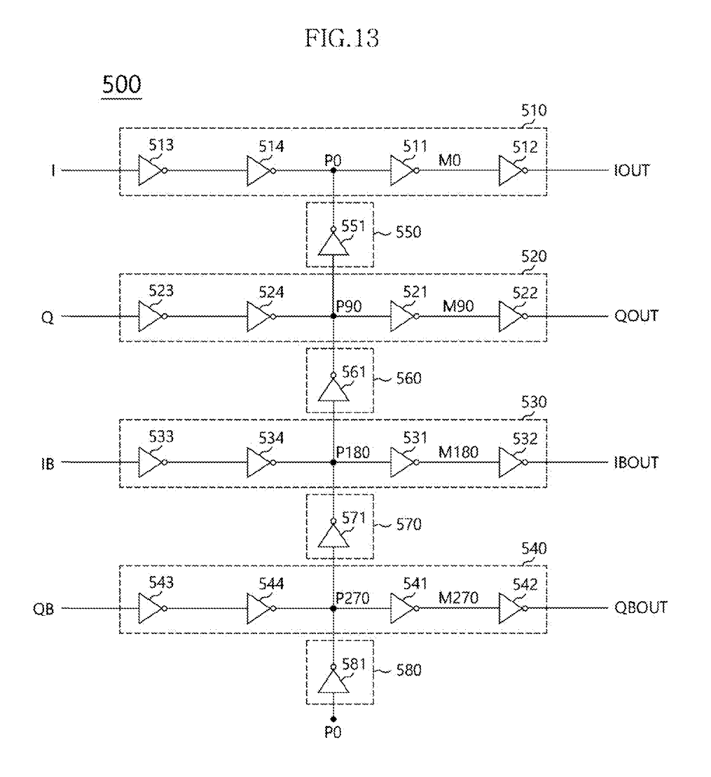

FIG. 12 is a wave diagram illustrating output signals IOUT, QOUT, IBOUT and QBOUT from the signal driver circuit 400 shown in FIG. 11. The first to fourth emphasis drivers 4120, 4220, 4320 and 4420 may perform an emphasis operation to the first to fourth output signals IOUT, QOUT, IBOUT and QBOUT, respectively. When the first output signal IOUT transits from a low level to a high level, the high level of the first output signal IOUT may have a level of the first high voltage VH1 and the high level of the first output signal IOUT may decrease to the second high voltage VH2 lower than the first high voltage VH1 by the first emphasis driver 4120. When the first output signal IOUT transits from a high level to a low level, the low level of the first output signal IOUT may have a level of the first low voltage VL1 and the low level of the first output signal IOUT may increase to the second low voltage VL2 higher than the first low voltage VL1 by the first emphasis driver 4120. When the second output signal QOUT transits from a low level to a high level, the high level of the second output signal QOUT may have a level of the first high voltage VH1 and the high level of the second output signal QOUT may decrease to the second high voltage VH2 lower than the first high voltage VH1 by the second emphasis driver 4220. When the second output signal QOUT transits from a high level to a low level, the low level of the second output signal QOUT may have a level of the first low voltage VL1 and the low level of the second output signal QOUT may increase to the second low voltage VL2 higher than the first low voltage VL1 by the second emphasis driver 4220. When the third output signal IBOUT transits from a low level to a high level, the high level of the third output signal IBOUT may have a level of the first high voltage VH1 and the high level of the third output signal IBOUT may decrease to the second high voltage VH2 lower than the first high voltage VH1 by the third emphasis driver 4320. When the third output signal IBOUT transits from a high level to a low level, the low level of the third output signal IBOUT may have a level of the first low voltage VL1 and the low level of the third output signal IBOUT may increase to the second low voltage VL2 higher than the first low voltage VL1 by the third emphasis driver 4320. When the fourth output signal QBOUT transits from a low level to a high level, the high level of the fourth output signal QBOUT may have a level of the first high voltage VH1 and the high level of the fourth output signal QBOUT may decrease to the second high voltage VH2 lower than the first high voltage VH1 by the fourth emphasis driver 4420. When the fourth output signal QBOUT transits from a high level to a low level, the low level of the fourth output signal QBOUT may have a level of the first low voltage VL1 and the low level of the fourth output signal QBOUT may increase to the second low voltage VL2 higher than the first low voltage VL1 by the fourth emphasis driver 4420.

FIG. 13 is a diagram illustrating a representation of an example of a configuration of a signal driver circuit 500 in accordance with an embodiment. Referring to FIG. 13, the signal driver circuit 500 may include a first main driver 510, a second main driver 520 and a first emphasis driver 550. The first main driver 510 may generate the first intermediate signal M0 by inverting a first phase signal P0, and may generate a first output signal IOUT by inverting the first intermediate signal M0. The second main driver 520 may generate the second intermediate signal M90 by inverting a second phase signal P90, and may generate a second output signal QOUT by inverting the second intermediate signal M90. For example, the second phase signal P90 may have a phase difference of 90 degrees from the first phase signal P0. The first emphasis driver 550 may invert the second phase signal P90, and may combine the inverted signal to the first phase signal P0. The first emphasis driver 550 may perform an emphasis operation to the first output signal IOUT.

The signal driver circuit 500 may further include a third main driver 530 and a second emphasis driver 560. The third main driver 530 may generate a third intermediate signal M180 by inverting a third phase signal P180, and may generate a third output signal IBOUT by inverting the third intermediate signal M180. For example, the third phase signal P180 may have a phase difference of 90 degrees from the second phase signal P90, and may have a phase difference of 180 degrees from the first phase signal P0. The second emphasis driver 560 may invert the third phase signal P180, and may combine the inverted signal to the second phase signal P90. The second emphasis driver 560 may perform an emphasis operation to the second output signal QOUT.

The signal driver circuit 500 may further include a fourth main driver 540, a third emphasis driver 570 and a fourth emphasis driver 580. The fourth main driver 540 may generate a fourth intermediate signal M270 by inverting a fourth phase signal P270, and may generate a fourth output signal QBOUT by inverting the fourth intermediate signal M270. For example, the fourth phase signal P270 may have a phase difference of 90 degrees from the third phase signal P180, may have a phase difference of 180 degrees from the second phase signal P90, and may have a phase difference of 270 degrees from the first phase signal P0. The third emphasis driver 570 may invert the fourth phase signal P270, and may combine the inverted signal to the third phase signal P180. The third emphasis driver 570 may perform an emphasis operation to the third output signal IBOUT. The fourth emphasis driver 580 may invert the first phase signal P0, and may combine the inverted signal to the fourth phase signal P270. The fourth emphasis driver 580 may perform an emphasis operation to the fourth output signal QBOUT. Through the first to fourth main drivers 510, 520, 530 and 540 and the first to fourth emphasis drivers 550, 560, 570 and 580, the signal driver circuit 500 may provide the same operation and effect as the signal driver circuit 400 described with reference to FIG. 11.

Referring to FIG. 13, the first main driver 510 may include a first inverter 511 and a second inverter 512. The first inverter 511 may output the first intermediate signal MO by inverting the first phase signal P0. The second inverter 512 may output the first output signal IOUT by inverting the first intermediate signal M0. The first emphasis driver 550 may include an inverter 551. The inverter 551 may invert the second phase signal P90, and may combine the inverted signal to the first phase signal P0. The first main driver 510 may further include a third inverter 513 and a fourth inverter 514. The third inverter 513 may receive a first input signal I, and may invert the first input signal I. The fourth inverter 514 may generate the first phase signal P0 by inverting the output of the third inverter 513.

The second main driver 520 may include a first inverter 521 and a second inverter 522. The first inverter 521 may output the second intermediate signal M90 by inverting the second phase signal P90. The second inverter 522 may output the second output signal QOUT by inverting the second intermediate signal M90. The second emphasis driver 560 may include an inverter 561. The inverter 561 may invert the third phase signal P180, and may combine the inverted signal to the second phase signal P90. The second main driver 520 may further include a third inverter 523 and a fourth inverter 524. The third inverter 523 may receive a second input signal Q, and may invert the second input signal Q. The fourth inverter 524 may generate the second phase signal P90 by inverting the output of the third inverter 523.

The third main driver 530 may include a first inverter 531 and a second inverter 532. The first inverter 531 may output the third intermediate signal M180 by inverting the third phase signal P180. The second inverter 532 may output the third output signal IBOUT by inverting the third intermediate signal M180. The third emphasis driver 570 may include an inverter 571. The inverter 571 may invert the third phase signal P180, and may combine the inverted signal to the second phase signal P90. The third main driver 530 may further include a third inverter 533 and a fourth inverter 534. The third inverter 533 may receive a third input signal IB, and may invert the third input signal IB. The fourth inverter 534 may generate the third phase signal P180 by inverting the output of the third inverter 533.

The fourth main driver 540 may include a first inverter 541 and a second inverter 542. The first inverter 541 may output the fourth intermediate signal M270 by inverting the fourth phase signal P270. The second inverter 542 may output the fourth output signal QBOUT by inverting the fourth intermediate signal M270. The fourth emphasis driver 580 may include an inverter 581. The inverter 581 may invert the first phase signal PO, and may combine the inverted signal to the fourth phase signal P270. The fourth main driver 540 may further include a third inverter 543 and a fourth inverter 544. The third inverter 543 may receive a fourth input signal QB, and may invert the fourth input signal QB. The fourth inverter 544 may generate the fourth phase signal P270 by inverting the output of the third inverter 543.

The first to fourth emphasis drivers 550, 560, 570 and 580 may be changed and/or modified to have various coupling relationships. In an embodiment, the first to fourth emphasis drivers 550, 560, 570 and 580 may be changed and/or modified such that the first emphasis driver 550 may be coupled between the second intermediate signal M90 and the first intermediate signal M0, the second emphasis driver 560 may be coupled between the third intermediate signal M180 and the second intermediate signal M90, the third emphasis driver 570 may be coupled between the fourth intermediate signal M270 and the third intermediate signal M180, and the fourth emphasis driver 580 may be coupled between the first intermediate signal M0 and the fourth intermediate signal M270. In an embodiment, the first to fourth emphasis drivers 550, 560, 570 and 580 may be changed and/or modified such that the first emphasis driver 550 may be coupled between the second input signal Q and the first input signal I, the second emphasis driver 560 may be coupled between the third input signal IB and the second input signal Q, the third emphasis driver 570 may be coupled between the fourth input signal QB and the third input signal IB, and the fourth emphasis driver 580 may be coupled between the first input signal I and the fourth input signal QB. In an embodiment, the first to fourth emphasis drivers 550, 560, 570 and 580 may be changed and/or modified such that the first emphasis driver 550 may be coupled between the second output signal QOUT and the first output signal IOUT, the second emphasis driver 560 may be coupled between the third output signal IBOUT and the second output signal QOUT, the third emphasis driver 570 may be coupled between the fourth output signal QBOUT and the third output signal IBOUT, and the fourth emphasis driver 580 may be coupled between the first output signal IOUT and the fourth output signal QBOUT. In an embodiment, the first to fourth emphasis drivers 550, 560, 570 and 580 may be changed and/or modified such that the first emphasis driver 550 may be coupled between the third and fourth inverters 523 and 524 of the second main driver 520 and the third and fourth inverters 513 and 514 of the first main driver 510, the second emphasis driver 560 may be coupled between the third and fourth inverters 533 and 534 of the third main driver 530 and the third and fourth inverters 523 and 524 of the second main driver 520, the third emphasis driver 570 may be coupled between the third and fourth inverters 543 and 544 of the fourth main driver 540 and the third and fourth inverters 533 and 534 of the third main driver 530, and the fourth emphasis driver 580 may be coupled between the third and fourth inverters 513 and 514 of the first main driver 510 and the third and fourth inverters 543 and 544 of the fourth main driver 540.

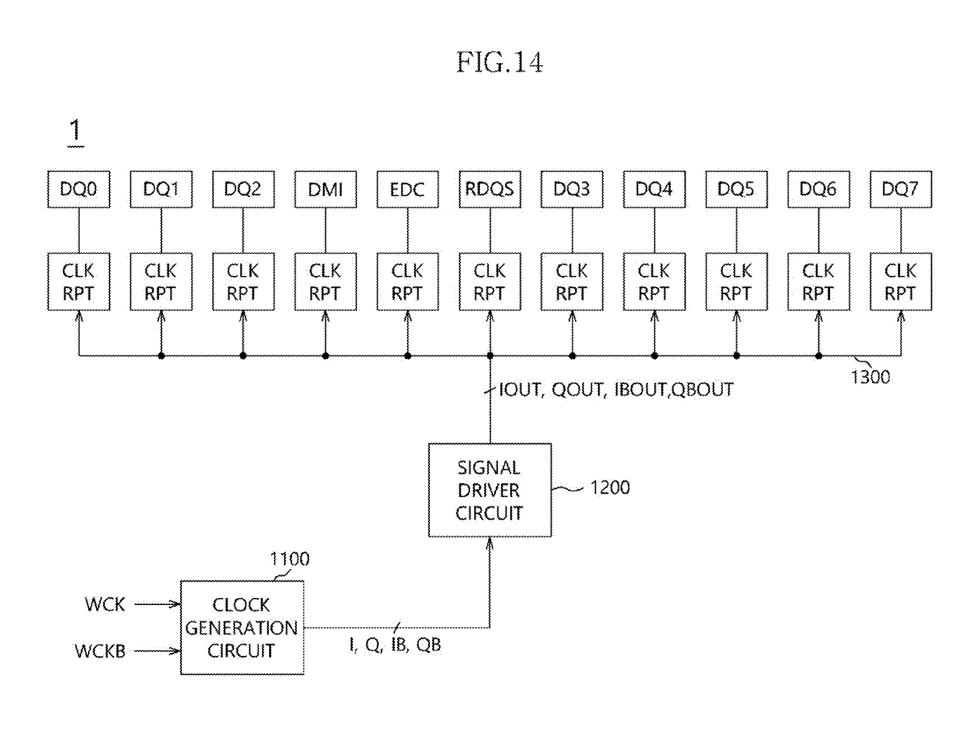

FIG. 14 is a diagram illustrating a representation of an example of a configuration of a semiconductor apparatus 1 in accordance with an embodiment. FIG. 14 shows the signal driver circuits in accordance with various embodiments applied to the semiconductor apparatus 1. Referring to FIG. 14, the semiconductor apparatus 1 may include a plurality of pads. The plurality of pads may be transmission paths for the semiconductor apparatus 1 to communicate with external apparatuses. A part of the plurality of pads may be two way signal transmission paths and the other part of the plurality of pads may be one way signal transmission paths. Through the plurality of pads, the semiconductor apparatus 1 may receive various signals from the external apparatuses and may transmit various signals to the external apparatuses. The various signals may be transmitted in synchronization with a clock signal. The plurality of pads may receive the various signals from the external apparatuses in synchronization with the clock signal, or may transmit the various signals to the external apparatuses in synchronization with the clock signal. The various signals may include data signal, data masking signal, error detection code, data strobe signal, and so forth. The data signal may be bi-directionally transmitted between the external apparatuses and the semiconductor apparatus 1. First to eighth data pads DQ0, DQ1, DQ2, DQ3, DQ4, DQ5, DQ6 and DQ7 may receive or transmit data of different streams from or to the external apparatuses in synchronization with the clock signal. The data masking signal may prevent a particular data signal from being written into the semiconductor apparatus 1. The data masking signal may be uni-directionally transmitted from the external apparatuses to the semiconductor apparatus 1. A data masking pad DMI may receive the data masking signal in synchronization with the clock signal. The error detection code may be information of an error detected from the semiconductor apparatus 1. The error detection code may be uni-directionally transmitted from the semiconductor apparatus 1 to the external apparatuses. An error detection code pad EDC may transmit the error detection code to the external apparatuses in synchronization with the clock signal. The data strobe signal may be synchronized with the transmission timing of the data signal when the semiconductor apparatus 1 transmits the data signal to the external apparatuses. A data strobe pad RDQS may generate the data strobe signal based on the clock signal.

The semiconductor apparatus 1 may include a clock generation circuit 1100 and a signal driver circuit 1200. The clock generation circuit 1100 may receive external clock signals WCK and WCKB, and may generate internal clock signals I, Q, IB and QB from the external clock signals WCK and WCKB. The external clock signals WCK and WCKB may be complementary to each other. The external clock signals WCK and WCKB may have relatively high frequencies, and the clock generation circuit 1100 may generate the internal clock signals I, Q, IB and QB by frequency-dividing the external clock signals WCK and WCKB. The clock generation circuit 1100 may generate multi-phase clock signals. For example, the internal clock signals I, Q, IB and QB may include four clock signals having a phase difference of 90 degrees from each other.

In order to provide the clock signal to the plurality of pads requiring the clock signal, the semiconductor apparatus 1 may include the signal driver circuit 1200. The signal driver circuit 1200 may receive the internal clock signals I, Q, IB and QB generated by the clock generation circuit 1100, and may generate output clock signals IOUT, QOUT, IBOUT and QBOUT by driving the internal clock signals I, Q, IB and QB. The signal driver circuit 1200 may provide the output clock signals IOUT, QOUT, IBOUT and QBOUT to the plurality of pads through a global line 1300. The signal driver circuit 1200 may be provided to transmit the output clock signals IOUT, QOUT, IBOUT and QBOUT to the plurality of pads at a prompt timing by stably driving the global line 1300 having a great length and a great loading. The signal driver circuit 1200 may be an essential element to form a stable clock distribution network of the semiconductor apparatus 1. One or more among the signal driver circuits 100A, 100B, 100C, 200A, 200B, 300A, 300B, 400 and 500 described with reference to FIGS. 1, 4, 6, 8A, 8B 9A, 9B, 11 and 13 may be applied as the signal driver circuit 1200 in accordance with various embodiments. The semiconductor apparatus 1 may further include a plurality of clock repeaters CLK RPT. The plurality of clock repeaters CLK RPT may be assigned to the plurality of pads, respectively. The plurality of clock repeaters CLK RPT may provide the clock signals to the plurality of pads by repeating the output clock signals IOUT, QOUT, IBOUT and QBOUT transmitted from the signal driver circuit 1200 through the global line 1300.

While certain embodiments have been described above, it will be understood to those skilled in the art that the embodiments described are by way of example only. Accordingly, the signal driver circuit for driving a signal and semiconductor apparatus using the same should not be limited based on the described embodiments. Rather, the signal driver circuit for driving a signal and semiconductor apparatus using the same described herein should only be limited in light of the claims that follow when taken in conjunction with the above description and accompanying drawings.

What is claimed is:

1. A signal driver circuit comprising:
a first inversion driver configured to receive a first signal, and to output a second signal by inversion-driving the first signal;
a second inversion driver configured to receive the second signal, and to output a third signal by inversion-driving the second signal; and
an emphasis driver configured to receive the third signal, to inversion-drive the third signal, and to combine the inversion-driven signal to the first signal.

2. The signal driver circuit of claim 1, further comprising:
an input inversion driver configured to receive an input signal, and to output the first signal by inversion-driving the input signal; and
an output inversion driver configured to receive the third signal, and to output an output signal by inversion-driving the third signal.

3. The signal driver circuit of claim 2, wherein the emphasis driver forms a peak of the output signal by performing an emphasis operation to the output signal, and a driving force of the emphasis driver is variable to adjust an amplitude of the peak of the output signal.

4. The signal driver circuit of claim 2, further comprising an emphasis driver configured to receive the output signal, to inversion-drive the output signal, and to combine the inversion-driven signal to the second signal.

5. The signal driver circuit of claim 4, wherein the emphasis driver configured to receive the output signal forms a peak of the output signal by performing an emphasis operation to the output signal, and a driving force of the emphasis driver is variable to adjust an amplitude of the peak of the output signal.

6. The signal driver circuit of claim 3, wherein the emphasis driver further includes a resistive-capacitive (RC) delay unit configured to form a peak of the output signal by performing the emphasis operation to the output signal, and to variably delay the third signal to adjust a pulse width of the peak of the output signal.

7. A signal driver circuit comprising:
2n numbers of inversion drivers configured to output a second signal by sequentially inversion-driving a first signal, where n is an integer equal to or greater than 1; and
an emphasis driver configured to inversion-drive the second signal, and to combine the inversion-driven signal to the first signal.

8. The signal driver circuit of claim 7, further comprising:
an input inversion driver configured to receive an input signal, and to output the first signal by inversion-driving the input signal at least n number of times; and
an output inversion driver configured to receive the second signal, and to output an output signal by inversion-driving the second signal at least n number of times.

9. The signal driver circuit of claim 8, wherein the emphasis driver forms a peak of the output signal by performing an emphasis operation to the output signal, and a driving force of the emphasis driver is variable to adjust an amplitude of the peak of the output signal.

10. The signal driver circuit of claim 9, wherein the signal driver circuit increases a pulse width of the peak as the n becomes greater.

11. A signal driver circuit comprising:
a first driver circuit configured to output a first output signal by inverting a first phase signal 2n number of times, to invert the first output signal, and to combine the inverted signal to the first phase signal,
wherein n is an integer equal to or greater than 1.

12. The signal driver circuit of claim 11,
further comprising a second driver circuit configured to output a second output signal by inverting a second phase signal 2n number of times, to invert the second output signal, and to combine the inverted signal to the second phase signal,
wherein the second phase signal has a phase difference of 90 degrees from the first phase signal.

13. The signal driver circuit of claim 12,
further comprising a third driver circuit configured to output a third output signal by inverting a third phase signal 2n number of times, to invert the third output signal, and to combine the inverted signal to the third phase signal,
wherein the third phase signal has a phase difference of 90 degrees from the second phase signal.

14. The signal driver circuit of claim 13,
further comprising a fourth driver circuit configured to output a fourth output signal by inverting a fourth phase signal 2n number of times, to invert the fourth output signal, and to combine the inverted signal to the fourth phase signal,
wherein the fourth phase signal has a phase difference of 90 degrees from the third phase signal.

15. The signal driver circuit of claim 14, wherein the first driver circuit includes:
a main driver having 2n numbers of inverters configured to generate the first output signal by inversion-driving the first phase signal in sequence; and
an emphasis driver having an inverter configured to inversion-drive the first output signal, and to combine the inversion-driven signal to the first phase signal.

16. The signal driver circuit of claim 14, wherein the second driver circuit includes:
to a main driver having 2n numbers of inverters configured to generate the second output signal by inversion-driving the second phase signal in sequence; and
an emphasis driver having an inverter configured to inversion-drive the second output signal, and to combine the inversion-driven signal to the second phase signal.

17. The signal driver circuit of claim 14, wherein the third driver circuit includes:
a main driver having 2n numbers of inverters configured to generate the third output signal by sequentially inversion-driving the third phase signal; and
an emphasis driver having an inverter configured to inversion-drive the third output signal, and to combine the inversion-driven signal to the third phase signal.

18. The signal driver circuit of claim 14, wherein the fourth driver circuit includes:
a main driver having 2n numbers of inverters configured to generate the fourth output signal by sequentially inversion-driving the fourth phase signal; and
an emphasis driver having an inverter configured to inversion-drive the fourth output signal, and to combine the inversion-driven signal to the fourth phase signal.

19. A signal driver circuit comprising:
a first main driver configured to generate a first intermediate signal by inverting a first phase signal, and to generate a first output signal by inverting the first intermediate signal;
a second main driver configured to generate a second intermediate signal by inverting a second phase signal, and to generate a second output signal by inverting the second intermediate signal, wherein the second phase signal has a phase difference of 90 degrees from the first phase signal; and
a first emphasis driver configured to invert the second phase signal, and to combine the inverted signal to the first phase signal; or configured to invert the second intermediate signal, and to combine the inverted signal to the first intermediate signal; or configured to invert the second output signal, and to combine the inverted signal to the first output signal.

20. The signal driver circuit of claim 19, further comprising:
a third main driver configured to generate a third intermediate signal by inverting a third phase signal, and to generate a third output signal by inverting the third intermediate signal, wherein the third phase signal has a phase difference of 90 degrees from the second phase signal; and
a second emphasis driver configured to invert the third phase signal, and to combine the inverted signal to the second phase signal; or configured to invert the third intermediate signal, and to combine the inverted signal to the second intermediate signal; or configured to invert the third output signal, and to combine the inverted signal to the second output signal.

21. The signal driver circuit of claim 20,
a fourth main driver configured to generate a fourth intermediate signal by inverting a fourth phase signal, and to generate a fourth output signal by inverting the fourth intermediate signal, wherein the fourth phase signal has a phase difference of 90 degrees from the third phase signal; and
a third emphasis driver configured to invert the fourth phase signal, and to combine the inverted signal to the third phase signal; or configured to invert the fourth intermediate signal, and to combine the inverted signal to the third intermediate signal; or configured to invert the fourth output signal, and to combine the inverted signal to the third output signal.

22. The signal driver circuit of claim 21, further comprising a fourth emphasis driver configured to invert the first phase signal, and to combine the inverted signal to the fourth phase signal; or configured to invert the first intermediate signal, and to combine the inverted signal to the fourth intermediate signal; or configured to invert the first output signal, and to combine the inverted signal to the fourth output signal.
